(19) United States
(12) Patent Application Publication
(10) Pub. No.: US 2014/0300402 A1
(43) Pub. Date: Oct. 9, 2014

(54) SIGNAL PROCESSING CIRCUIT

(71) Applicant: ALPS ELECTRIC CO., LTD., Tokyo (JP)

(72) Inventor: Masaki YAMAMOTO, Tokyo (JP)

(73) Assignee: ALPS ELECTRIC CO., LTD., Tokyo (JP)

(21) Appl. No.: 14/173,109

(22) Filed: Feb. 5, 2014

(30) Foreign Application Priority Data
Apr. 9, 2013 (JP) 2013-081242

(51) Int. Cl. H03K 5/08

(52) U.S. Cl. CPC H03K 5/08
USPC 327/328

(57) ABSTRACT

A signal processing circuit includes a detection circuit detecting a high frequency signal being input; and an output signal adjustment circuit which is provided in a rear end of the detection circuit and includes a first field effect transistor and a second field effect transistor. The first field effect transistor has a drain connected to an output end of the detection circuit, a source connected to a gate of the second field effect transistor, and a gate connected to a drain of the second field effect transistor. The second field effect transistor has a source connected to a ground. An output signal is output from the source of the first field effect transistor. When an input level of the high frequency signal is equal to or higher than a predetermined level, a magnitude of the output signal is maintained at a predetermined magnitude.

### CLAIM OF PRIORITY

This application claims benefit of Japanese Patent Application No. 2013-081242 filed on Apr. 9, 2013, which is hereby incorporated by reference.

### BACKGROUND OF THE INVENTION

1. Field of the Invention

The present invention relates to a signal processing circuit treating a high frequency signal, and particularly to a signal processing circuit including a detection circuit.

2. Description of the Related Art

In the related art, in a signal processing circuit treating a high frequency signal of a broadcast reception device or a communication device, a detection circuit for outputting a voltage according to an input level of the received high frequency signal has been provided. In addition, a signal processing circuit has been proposed which is configured to include an amplification circuit provided in a front end of the detection circuit, and an automatic gain control (AGC) circuit for controlling amplification degree of the amplification circuit, according to a magnitude of a voltage output from the detection circuit.

As the signal processing circuit, an invention described in Japanese Unexamined Patent Application Publication No. 2003-152482 is disclosed.

An AM receiver 900 described in Japanese Unexamined Patent Application Publication No. 2003-152482 is illustrated in FIG. 10. The AM receiver 900 is configured to include a high frequency amplification circuit 911, a mixing circuit 912, a local oscillator 913, an intermediate frequency filter 914, an intermediate frequency amplification circuit 915, an AM detection circuit 916, and an AGC circuit 917. After an AM modulation wave signal received by an antenna 910 is amplified by the high frequency amplification circuit 911, and the amplified signal is mixed with a local oscillation signal output from the local oscillator 913, and a conversion into an intermediate frequency signal is performed.

The AM detection circuit 916 outputs an audio signal by performing AM detection processing with respect to the intermediate frequency signal amplified by the intermediate frequency amplification circuit 915. The AGC circuit 917 controls a gain of the intermediate frequency amplification circuit 915, in such a manner that an average level of an output signal of the AM detection circuit 916 is substantially constant.

However, in the AM receiver 900 described in Japanese Unexamined Patent Application Publication No. 2003-152482, many circuit elements were required to be used in the AGC circuit 917, and thus a circuit size of the AGC circuit 917 had to be increased. In addition, since attenuation means were required to be provided even in the intermediate frequency amplification circuit 915 controlled by a signal from the AGC circuit 917, a circuit size has been increased. Thus, there is a problem that in the signal processing circuit using the AGC circuit such as the invention described in Japanese Unexamined Patent Application Publication No. 2003-152482, a size of the whole circuit is increased.

### SUMMARY OF THE INVENTION

The present invention provides a signal processing circuit which includes an output signal adjustment circuit for maintaining a magnitude of an output signal at a predetermined magnitude, when an input level of a high frequency signal being input is equal to or higher than a predetermined level, and whose circuit size is reduced.

The signal processing circuit according to an embodiment of the present invention includes a detection circuit detecting a high frequency signal being input; and an output signal adjustment circuit which is provided in a rear end of the detection circuit and includes a first field effect transistor and a second field effect transistor. The first field effect transistor has a drain connected to an output end of the detection circuit, a source connected to a gate of the second field effect transistor, and a gate connected to a drain of the second field effect transistor. The second field effect transistor has a source connected to a ground. An output signal is output from the source of the first field effect transistor. When an input level of the high frequency signal is equal to or higher than a predetermined level, a magnitude of the output signal is maintained at a predetermined magnitude.

In the signal processing circuit configured in this way, the output signal adjustment circuit in which the magnitude of the output signal is maintained to the predetermined magnitude, when the input level of the high frequency signal is equal to or higher than the predetermined level, is configured by combining the first field effect transistor and the second field effect transistor, and thereby the circuit can be configured using a small number of elements. Thus, it is possible to easily provide the signal processing circuit which has the output signal adjustment circuit and a small circuit size.

In addition, in the above-described configuration, the signal processing circuit according to the embodiment of the present invention may include a power supply terminal; a first resistor connected from the gate of the first field effect transistor to the power supply terminal; a second resistor connected from a connection point between the gate of the first field effect transistor and the first resistor to drain of the second field effect transistor; a third resistor connected from the source of the second field effect transistor to the ground; and a fourth resistor connected from the source of the first field effect transistor to the ground.

In the signal processing circuit configured in this way, a resistance value of each of the first resistor, the second resistor, the third resistor, and the fourth resistor is appropriately set, and thereby it is possible to easily adjust the magnitude of the output signal so as to be included within an allowable input voltage of the circuit connected to the rear stage.

In the signal processing circuit according to the embodiment of the present invention, the output signal adjustment circuit in which the magnitude of the output signal is maintained to the predetermined magnitude, when the input level of the high frequency signal is equal to or higher than the predetermined level, is configured by combining the first field effect transistor and the second field effect transistor, and thereby the circuit can be configured using a small number of elements. Thus, it is possible to easily provide the signal processing circuit which has the output signal adjustment circuit and a small circuit size.

### BRIEF DESCRIPTION OF THE DRAWINGS

FIG. 1 is a circuit diagram illustrating a configuration of a signal processing circuit according to an embodiment of the present invention;

FIG. 2A is a circuit diagram illustrating a configuration of a detection circuit used in the signal processing circuit according to the embodiment of the present invention;

FIG. 2B is a circuit diagram illustrating another configuration of the detection circuit used in the signal processing circuit according to the embodiment of the present invention;

FIG. 3 is a graph illustrating a detection signal with respect to an input level of a first detection circuit illustrated in FIG. 2A;

FIG. 4 is a graph illustrating a detection signal with respect to an input level of a second detection circuit illustrated in FIG. 2B;

FIG. 5 is an equivalent circuit diagram for explaining an operation of an output signal adjustment circuit in the signal processing circuit according to the embodiment of the present invention;

FIGS. 6A and 6B are each graphs illustrating a relationship between a control voltage and an output signal with respect to the input level, of the signal processing circuit according to the embodiment of the present invention;

FIG. 7 is an equivalent circuit diagram at the time of a first mode in the equivalent circuit diagram of FIG. 5;

FIG. 8 is an equivalent circuit diagram at the time of a second mode in the equivalent circuit diagram of FIG. 5;

FIG. 9 is an equivalent circuit diagram at the time of a third mode in the equivalent circuit diagram of FIG. 5; and

FIG. 10 is a block diagram illustrating a configuration of a signal processing circuit according to an example of the related art.

### DESCRIPTION OF THE PREFERRED EMBODIMENTS

### Embodiment

Hereinafter, an embodiment of the present invention will be described with reference to the drawings.

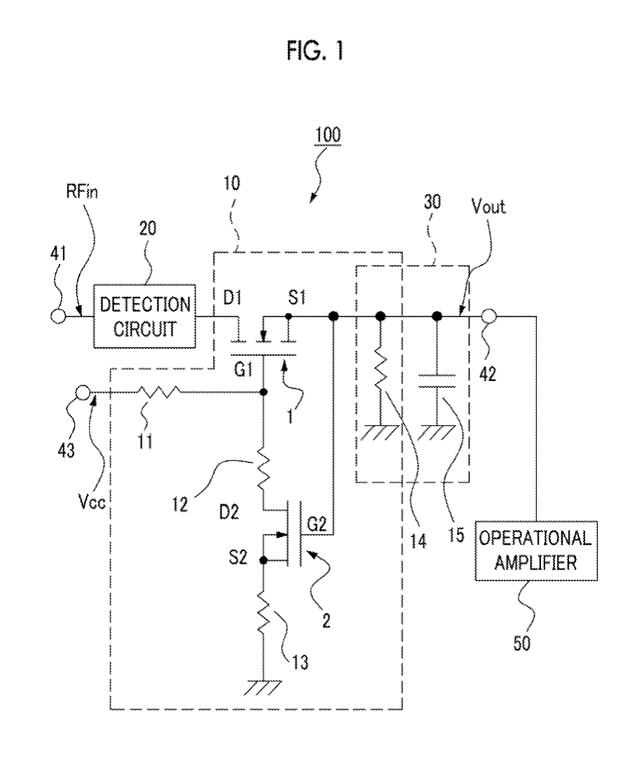

FIG. 1 is a circuit diagram illustrating a configuration of a signal processing circuit 100 according to the embodiment of the present invention.

The signal processing circuit 100 according to the embodiment of the present invention includes an output signal adjustment circuit 10, a detection circuit 20, and a smoothing circuit 30. The detection circuit 20 is connected to an input terminal 41, and outputs a detection signal obtained by detecting a high frequency signal being input to the output signal adjustment circuit 10 of the next stage. The output signal adjustment circuit 10 is configured so as to process the detection signal from the detection circuit 20, and to output the signal as a value equal to or lower than a predetermined value. Meanwhile, a configuration and an operation of the output signal adjustment circuit 10 will be described in detail later.

The smoothing circuit 30 is a circuit in which a fourth resistor 14 and a capacitor 15 are connected in parallel to each other, and which are connected from an output terminal 42 of the signal processing circuit 100 to a ground. The smoothing circuit 30 smoothes a signal output from the output signal adjustment circuit 10, and outputs the smoothed signal to an operational amplifier 50 connected to a rear stage.

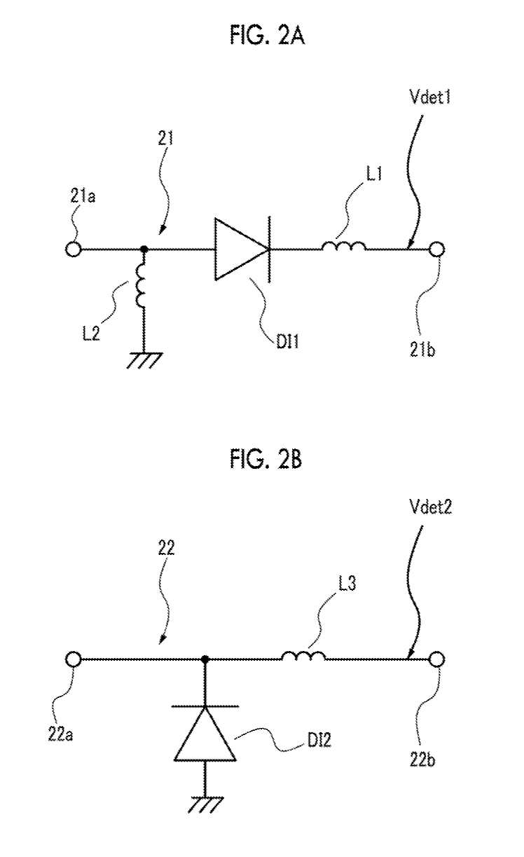

Next, a configuration of the detection circuit 20 will be described using FIGS. 2A to 4. Meanwhile, the signal processing circuit 100 uses one of a first detection circuit 21 and a second detection circuit 22 as the detection circuit 20. These two detection circuits will each be described.

In FIG. 2A, the first detection circuit 21 including a diode DI1 of a type connected in series from an input terminal 21a to an output terminal 21b, is illustrated. An anode of the diode DI1 is connected to the input terminal 21a, and a cathode of the diode DI1 is connected to the output terminal 21b through an inductor L1 for blocking high frequency signal components contained in an input signal. In addition, from the anode of the diode DI1 to the ground, an inductor L2 for removing dc components contained in the input signal is connected. The signal input to the input terminal 21 a is detected by the diode DI1, and a detection signal Vdet1 is output from the output terminal 21b.

In FIG. 2B, the second detection circuit 22 including a diode DI2 of a type connected from an input terminal 22a to a ground, is illustrated. A cathode of the diode DI2 is connected to the input terminal 22a, and an anode of the diode DI2 is connected to the ground. In addition, from the cathode of the diode DI2 to the output terminal 22b, an inductor L3 for blocking the high frequency signal components contained in the input signal is connected. The signal input to the input terminal 22a is detected by the diode DI2, and a detection signal Vdet2 is output from the output terminal 22b. Meanwhile, hereafter, Vdet is used to collectively refer to the detection signals Vdet1 and Vdet2.

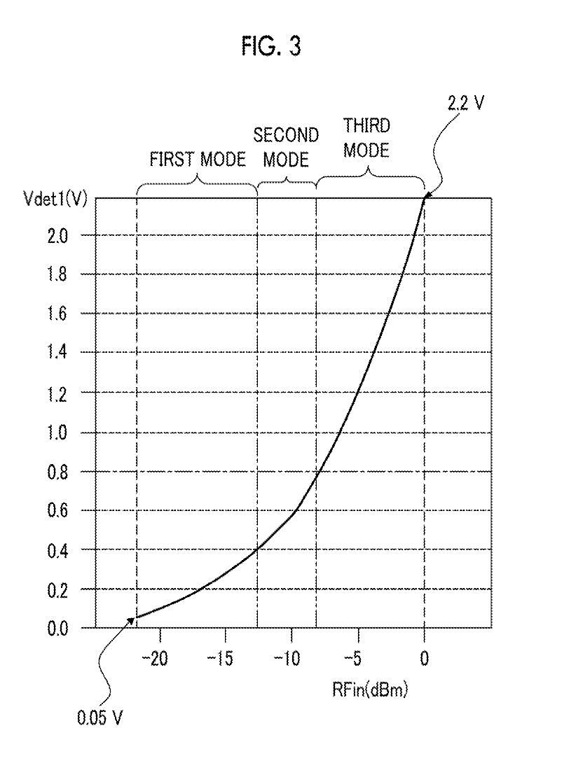

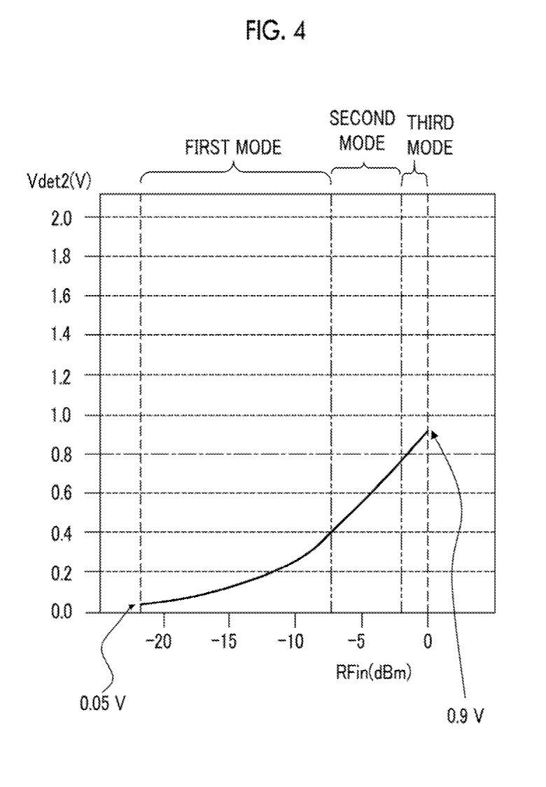

Next, when high frequency signals are input to the first detection circuit 21 and the second detection circuit 22, graphs of each of the detection signals Vdet1 and Vdet2 are illustrated in FIGS. 3 and 4. A vertical axis of the graph denotes the detection signal Vdet (V), and a horizontal axis thereof denotes the input level RFin (dBm) of the high frequency signal. In addition, one-dot chain line in this graph is a line which represents an upper limit (0.8 V in this case) of an allowable input voltage of the operational amplifier 50 illustrated in FIG. 1. It is assumed that as a range of the input level RFin of the high frequency signal, a range between a lower limit of −22 dBm and an upper limit of 0 dBm is set. The lower limit and the upper limit of the input level RFin of the high frequency signal are each represented by a dashed line. In addition, the input level RFin is divided into a first mode, a second mode, and a third mode in ascending order, depending on values thereof, and boundaries between those are each represented by a two-dot chain line. Meanwhile, the range of each of the first mode, the second mode, and the third mode depends on a type of the detection circuit 20 being used, that is, the first detection circuit 21 or the second detection circuit 22.

According to FIG. 3, the detection signal Vdet1 generated by the first detection circuit 21 changes from 0.05 V to 2.2 V, while the input level RFin is varied from −22 dBm to 0 dBm. According to FIG. 4, the detection signal Vdet2 generated by the second detection circuit 22 varies from 0.05 V to 0.9 V, while the input level RFin is varied from −22 dBm to 0 dBm.

Thus, when the detection signal Vdet of the first detection circuit 21 or the second detection circuit 22 is input to the operational amplifier 50 (refer to FIG. 1) of the rear stage as it is, the detection signal Vdet exceeds the upper limit of the allowable input voltage of the operational amplifier 50, by a value of the input level RFin of the high frequency signal. Thus, when the input level RFin of the high frequency signal becomes a level equal to or more than a predetermined level, the output signal adjustment circuit 10 is required to be set, in such a manner that an output signal Vout is maintained constantly, and the input voltage to the operational amplifier 50 does not exceed the upper limit of the allowable input voltage of the operational amplifier 50.

Next, using FIG. 1, a configuration of the output signal adjustment circuit 10 in the signal processing circuit 100 according to the embodiment of the present invention will be described.

As illustrated in FIG. 1, the output signal adjustment circuit 10 is configured by six circuit elements which includes a first field effect transistor 1, a second field effect transistor 2, a first resistor 11, a second resistor 12, a third resistor 13, and the fourth resistor 14. Meanwhile, the fourth resistor 14 is shared with the smoothing circuit 30.

A drain D1 of the first field effect transistor 1 is connected to an output end of the detection circuit 20, a source S1 thereof is connected to the output terminal 42, a gate G1 thereof is connected to a power supply terminal 43 through the first resistor 11, and the source S1 thereof is connected to the ground through the fourth resistor 14. From a connection point between the gate G1 of the first field effect transistor 1 and the first resistor 11 to a drain D2 of the second field effect transistor 2, the second resistor 12 is connected. A source S2 of the second field effect transistor 2 is connected to the ground through the third resistor 13. Then, a gate G2 of the second field effect transistor 2 is connected to the source S1 of the first field effect transistor 1. In addition, a supply voltage Vcc is supplied to the power supply terminal 43.

Next, using FIGS. 1 to 9, an operation of the output signal adjustment circuit 10 in the signal processing circuit 100 according to the embodiment of the present invention will be described.

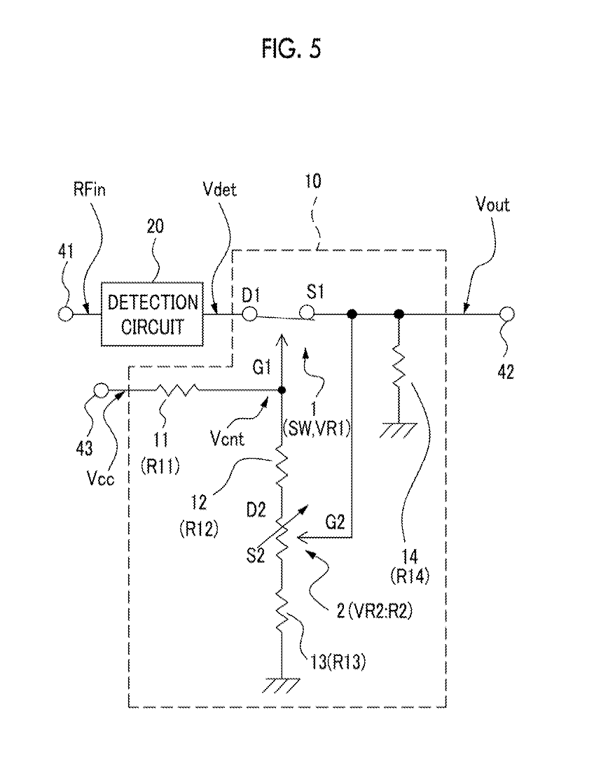

FIG. 5 is an equivalent circuit diagram for explaining the operation of the output signal adjustment circuit 10 in the signal processing circuit 100 according to the embodiment of the present invention. Meanwhile, in the output signal adjustment circuit 10, gate threshold voltages of the first field effect transistor 1 and the second field effect transistor 2 are set to approximately 0.35 V, and the supply voltage Vcc applied to the power supply terminal 43 is set to 3.3 V.

In general, depending on how to use, a field effect transistor can be considered as a variable resistor which is varied by a magnitude of gate-source voltage thereof, or as a switching element. Thus, in each field effect transistor in the output signal adjustment circuit 10, as illustrated in FIG. 5, according to a way of using, the first field effect transistor 1 can be replaced with a switching element SW, and the second field effect transistor 2 can be replaced with a variable resistor VR2. In addition, the first field effect transistor 1 can also be replaced with a variable resistor VR1 according to a mode at that time. Thus, the switching element SW or the variable resistor VR1 is controlled by a voltage, that is, a control voltage Vcnt which is applied to the gate G1 of the first field effect transistor 1. In addition, the variable resistor VR2 is controlled by a voltage, that is, the output signal Vout which is applied to the gate G2 of the second field effect transistor 2.

As illustrated in FIG. 5, the detection signal Vdet output from the detection circuit 20 is input to the drain D1 of the first field effect transistor 1. In addition, the output signal Vout from the source S1 of the first field effect transistor 1 is applied to the gate G2 of the second field effect transistor 2. Here, if it is assumed that a resistance value of the first resistor 11 is R11, a resistance value of the second resistor 12 is R12, a resistance value of the third resistor 13 is R13, and a resistance value of the variable resistor VR2 is R2, a voltage in which the supply voltage Vcc is divided by a resistance ratio between the resistance R11 and a combined resistance of the resistances R12, R2, and R13, is applied to the gate G1 of the first field effect transistor 1. That is, the control voltage Vcnt which is applied to the gate G1 of the first field effect transistor 1 is obtained by the following equation.

A first equation: Vcnt=Vcc×(R12+R2+R13)/(R11+R12+R2+R13)

In the output signal adjustment circuit 10 of the signal processing circuit 100 according to the embodiment of the present invention, the values of R11, R12, and R13 are each a constant value, but the resistance value R2 of the variable resistor VR2 is varied by a voltage of the gate G2 with respect to the source S2 of the second field effect transistor 2. When a voltage applied to the gate G2 with respect to the source S2 is significantly small, the second field effect transistor 2 is in a cut-off state, the resistance value R2 of the variable resistor VR2 becomes significantly large, and thereby a relationship of R2>>R11 is established. Thus, the first equation described above becomes a second equation which Vcnt=Vcc.

In addition, when the voltage applied to the gate G2 of the second field effect transistor 2 is significantly large, the second field effect transistor 2 is in a saturation state, the resistance value R2 of the variable resistor VR2 becomes significantly small, and R2 is regarded as approximately 0Ω. Thus, the first equation described above becomes a third equation which Vcnt=Vcc×(R12+R13)/(R11+R12+R13).

In addition, after the voltage of the gate G2 with respect to the source S2 of the second field effect transistor 2 exceeds the gate threshold voltage, and until the second field effect transistor 2 is in the saturation state (when being in a linear area), the resistance value R2 of the variable resistor VR2 becomes a meaningful value. For this reason, the first equation described above is represented in the same manner as

Vcnt=Vcc×(R12+R2+R13)/(R11+R12+R2+R13).

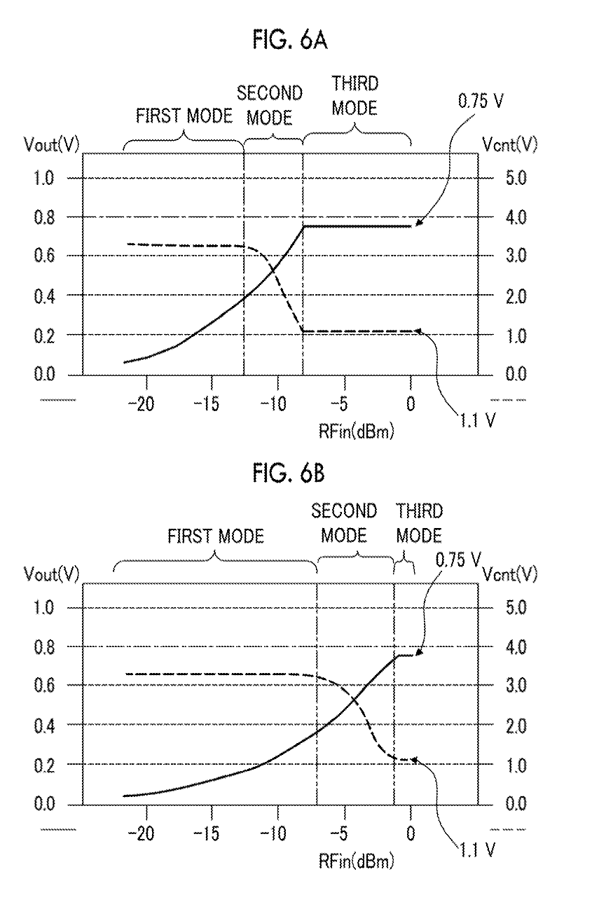

In FIG. 6A and 6B, a relationship between the control voltage Vcnt and the output signal Vout with respect to the input level RFin of the high frequency signal is illustrated. FIG. 6A is a graph illustrating a case where the first detection circuit 21 illustrated in FIG. 2A is used, and FIG. 6B is a graph illustrating a case where the second detection circuit 22 illustrated in FIG. 2B is used. In addition, in FIGS. 6A and 6B, the control voltage Vcnt is represented by a dashed line, and the output signal Vout is represented by a solid line. Then, in the same manner as in FIGS. 3 and 4, a mode in a state where the input level RFin is low is set as the first mode, a mode in a state where the input level RFin is medium level is set as the second mode, and a mode in a state where the input level RFin is high is set as the third mode.

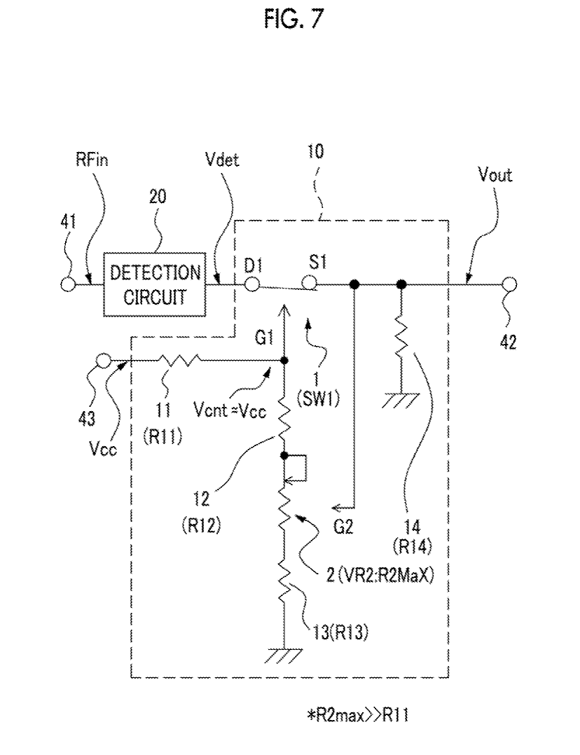

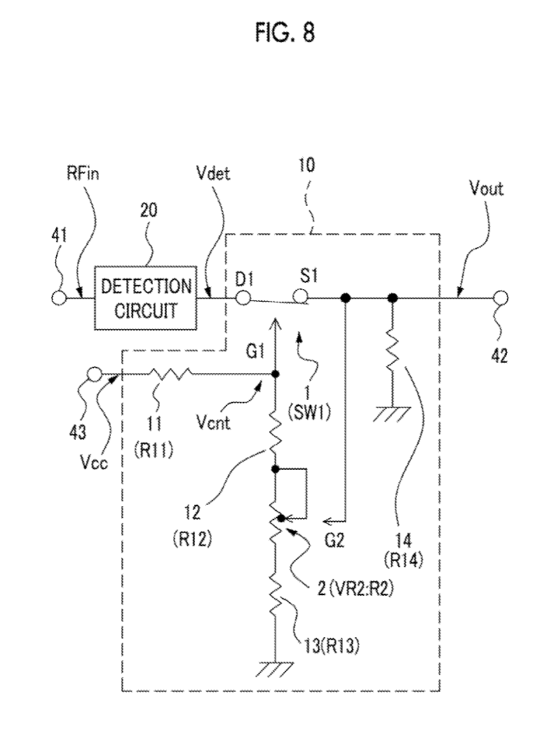

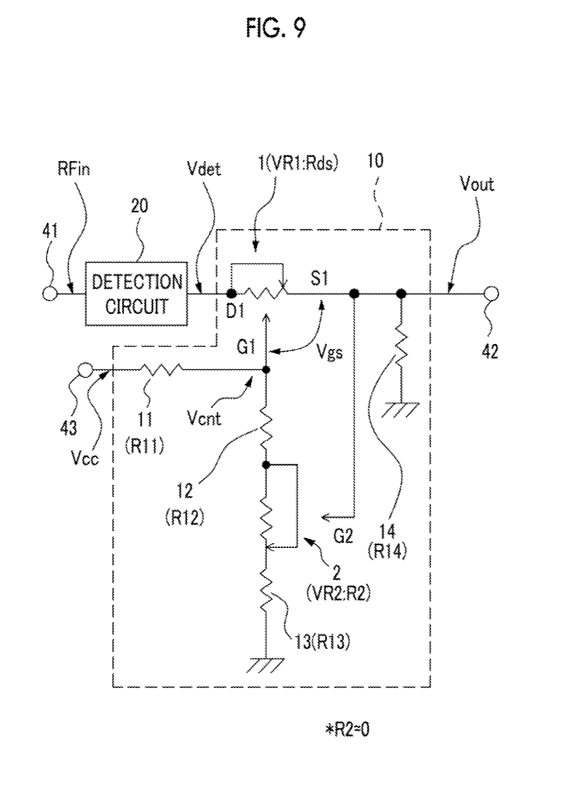

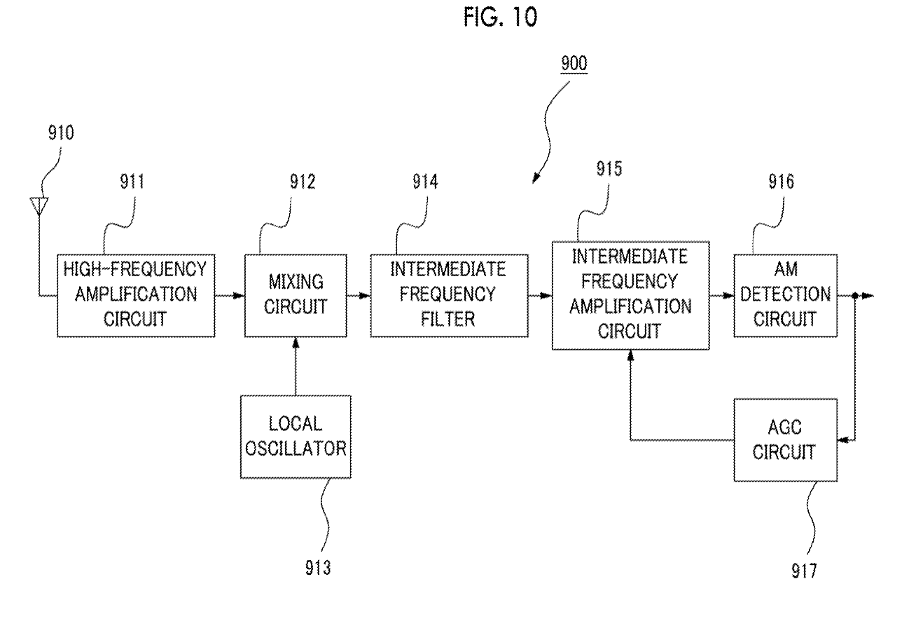

An equivalent circuit of the output signal adjustment circuit 10 in the first mode is illustrated in FIG. 7, an equivalent circuit of the output signal adjustment circuit 10 in the second mode is illustrated in FIG. 8, and an equivalent circuit of the output signal adjustment circuit 10 in the third mode is illustrated in FIG. 9.

In a case where the detection circuit 20 is the first detection circuit 21, when the high frequency signal is input to the input terminal 41, a relationship between the input level RFin, the control voltage Vcnt, and the output signal Vout will be described using FIGS. 3, 5, 6A, 7, 8 and 9.

In an initial state where the input level RFin does not exist before the output signal adjustment circuit 10 enters the first mode, as illustrated in FIG. 5, the gate G2 of the second field effect transistor 2 is in a state grounded through the fourth resistor 14, and thus the second field effect transistor 2 is in the cut-off state. For this reason, the supply voltage Vcc from the power supply terminal 43 is supplied to the gate G1 of the first field effect transistor 1, and the first field effect transistor 1 is in a conduction state.

Next, at the time of the first mode, as illustrated in FIG. 3, the input level RFin of the high frequency signal input to the input terminal 41 is low (equal to or lower than approximately −12.5 dBm), and thus the detection signal Vdet1 becomes equal to or less than approximately 0.4 V. When moving from the initial state to the first mode, the first field effect transistor 1 is already in the conduction state, and thus a voltage of the detection signal Vdet1 is applied to the gate G2 of the second field effect transistor 2 through the drain and source of the first field effect transistor 1. Then, at the time of the first mode, a voltage of the gate G2 with respect to the source S2 of the second field effect transistor 2 is designed so as to be equal to or lower than the gate threshold voltage of the second field effect transistor 2. In other words, at the time of the first mode, the voltage of the gate G2 with respect to the source S2 becomes a voltage equal to or lower than the gate threshold voltage of the second field effect transistor 2, and thereby the second field effect transistor 2 is maintained to the cut-off state. Thus, the resistance value R2 of the variable resistor VR2 becomes a maximum resistance R2max, and thus a relationship of R2>>R11 is established. Thus, as represented by the second equation, it is possible to be regarded as Vcnt≈Vcc. The equivalent circuit of the output signal adjustment circuit 10 in the first mode is illustrated in FIG. 7.

Thus, to the gate G1 of the first field effect transistor 1, approximately the same voltage (3.3 V) as the supply voltage Vcc is applied as the control voltage Vcnt, and the control voltage Vcnt exceeds greatly the gate threshold voltage of the first field effect transistor 1. Thus, as illustrated in FIG. 7, the switching element SW which is the first field effect transistor 1 is in the conduction state, and the detection signal Vdet1 appears substantially as it is, in the output terminal 42 as the output signal Vout.

As described above, in the first mode, since the detection signal Vdet1 appears to be substantially the output signal Vout, the output signal Vout in the first mode, as represented by the solid line in the first mode in FIG. 6A, is almost the same as the graph in the first mode of the detection signal Vdet1 illustrated in FIG. 3. At this time, the control voltage Vcnt is almost the same as the supply voltage Vcc, a value thereof is substantially constant, and the control voltage Vcnt is represented by a dashed line in the first mode in FIG. 6A.

Next, at the time of the second mode, as illustrated in FIG. 3, the input level RFin of the high frequency signal input to the input terminal 41 is from approximately −12.5 dBm to approximately −8 dBm, and the detection signal Vdet1 is from approximately 0.4 V to approximately 0.75 V. At this time, after the second field effect transistor 2 exceeds the cut-off area, and before entering the saturation area, the second field effect transistor 2 is in a linear area. Thus, the control voltage Vcnt is represented by the first equation described above, and Vcnt=Vcc×(R12+R2+R13)/(R11+R12+R2+R13). The equivalent circuit of the output signal adjustment circuit 10 in the second mode is illustrated in FIG. 8.

The control voltage Vcnt represented by the first equation described above is applied to the gate G1 of the first field effect transistor 1. Here, the resistance value R11 of the first resistor 11, the resistance value R12 of the second resistor 12, and the resistance value R13 of the third resistor 13 are set in such a manner that the control voltage Vcnt maintains the first field effect transistor 1 in the conduction state until the resistance value R2 of the variable resistor VR2 becomes approximately 0Ω. In other words, in the second mode, by appropriately setting the resistance values R11, R12 and R13, the voltage (Vgs) of the gate G1 with respect to the source S1 of the first field effect transistor 1 is set as a predetermined voltage exceeding the gate threshold voltage. Thus, as illustrated in FIG. 8, the switching element SW which is the first field effect transistor 1 is in the conduction state, and the detection signal Vdet1 appears to be substantially the output signal Vout in the output terminal 42.

As described above, in the second mode, since the detection signal Vdet1 appears substantially as it is as the output signal Vout, the output signal Vout, as represented by the solid line in the first mode in FIG. 6A, is almost the same as the graph of the detection signal Vdet1 illustrated in FIG. 3. At this time, the control voltage Vcnt is varied so as to be represented by the dashed line in the first mode in FIG. 6A.

Next, at the time of the third mode, as illustrated in FIG. 3, the input level RFin of the high frequency signal input to the input terminal 41 is from approximately −8 dBm to approximately 0 dBm, and the detection signal Vdet1 is from approximately 0.75 V to approximately 2.2 V. When moving from the second mode time to the third mode time, the second field effect transistor 2 enters the saturation state. In other words, at the time of the third mode, the voltage of the gate G2 with respect to the source S2 is set so as to cause the second field effect transistor 2 to be in the saturation state. At this time, the resistance value R2 of the variable resistor VR2 becomes almost 0Ω. Thus, the control voltage Vcnt is obtained by a third equation that Vcnt=Vcc×(R12+R13)/(R11+R12+R13), and accordingly becomes a constant value. The equivalent circuit of the output signal adjustment circuit 10 in the third mode is illustrated in FIG. 9.

As described above, when moving from the second mode time to the third mode time, the second field effect transistor 2 is in the saturation state, and thus the control voltage Vcnt becomes a constant value. Then, if the input level RFin of the high frequency signal input to the input terminal 41 increases, the detection signal Vdet1 also increases. Then, the output signal Vout also increases, but the control voltage Vcnt is constant, and thus the voltage (Vgs) of the gate G1 with respect to the source S1 of the first field effect transistor 1 decreases when the output signal Vout increases. For this reason, when the first field effect transistor 1 is replaced with the variable resistor VR1, the resistance value of the variable resistor VR1, that is, a resistance value Rds between the drain D1 and the source S1 of the first field effect transistor 1 increases. As a result, a signal obtained by dividing the detection signal Vdet1 using the resistance value Rds and the resistance value R14 of the fourth resistor 14 appears at the output terminal 42 as the output signal Vout. That is, an equation Vout=Vdet1×R14/(Rds+R14) is established. As the input level RFin of the high frequency signal output to the input terminal 41 increases, operation thereof is repeated, and thus as a result, the output signal Vout is maintained at a constant magnitude.

In the signal processing circuit 100 according to the present embodiments, as illustrated in FIG. 6A, at the time of the third mode, Vcnt=1.1 V, and the output signal Vout becomes constant at Vout=0.75 V.

In this way, in the third mode, when the input level RFin of the high frequency signal being input is equal to or higher than a predetermined level, in this case equal to or higher than approximately −8 dBm, the magnitude of the output signal Vout can be maintained constantly.

The embodiment of the present invention is configured in such a manner that the input voltage to the operational amplifier 50 does not exceed the upper limit of the allowable input voltage of the operational amplifier 50. For this reason, the setting may be made, in such a manner that the magnitude of the output signal Vout at the time of the third mode is smaller than the allowable input voltage of the operational amplifier 50 connected to the rear stage of the output signal adjustment circuit 10. Here, the setting is made to 0.75 V with respect to 0.8 V which is the allowable input voltage of the operational amplifier 50.

Up to now, a case where the first detection circuit 21 in FIG. 2A is used as the detection circuit 20 is described, but even in a case where the second detection circuit 22 in FIG. 2B is used, the operations are the same as each other. In a case where the second detection circuit 22 is used, as illustrated in FIG. 6B, if the input level RFin is equal to or lower than approximately −7 dBm, the input level RFin is regarded as the first mode in a low area. In addition, if the input level RFin is from approximately −7 dBm to approximately −1.5 dBm, the input level RFin is regarded as the second mode in a medium area, and if the input level RFin is equal to or higher than approximately −1.5 dBm, the input level RFin is regarded as the third mode in a high area. In addition, even in a case where the second detection circuit 22 is used, as illustrated in FIG. 6B, the magnitude of the output signal Vout is controlled so as to be constant at approximately 0.75 V, in the third mode in the area where the input level RFin is high, in the same manner as in a case where the first detection circuit 21 is used.

In this way, even in a case where the first detection circuit 21 in FIG. 2A is used, and a case where the second detection circuit 22 in FIG. 2B is used, the magnitude of the output signal Vout is controlled so as to be constant at maximum approximately 0.75 V, in the area where the input level RFin is high. Thus, in the signal processing circuit 100 according to the embodiments of the present invention, the magnitude of the output signal Vout does not exceed the upper limit (0.8 V) of the allowable input voltage of the operational amplifier 50 in the rear stage illustrated in FIG. 1.

In this way, in the signal processing circuit 100 according to the embodiments of the present invention, the maximum value of the output signal Vout is set to a value (0.75 V) lower than the upper limit (0.8 V) of the allowable input voltage. This value can be set by appropriately varying the resistance value R11 of the first resistor 11, the resistance value R12 of the second resistor 12, the resistance value R13 of the third resistor 13, and the resistance value R14 of the fourth resistor 14 which are illustrated in FIG. 5. Meanwhile, in the embodiment of the present invention, since the relationship between the input level RFin of the high frequency signal and the output signal Vout is correctly set, each of the resistance values of the second resistor 12 and the third resistor 13 is set as a predetermined resistance value. But, within a range in which the operation is not disturbed, the resistance value of one of the second resistor 12 and the third resistor 13 can be set to 0Ω In other words, one of the second resistor 12 and the third resistor 13 is removed, and the drain D1 and the source S1 of the first field effect transistor may be connected from the gate G1 of the first field effect transistor to the ground.

As described above, the output signal adjustment circuit 10 which is configured in such a manner that the magnitude of the output signal Vout is constantly maintained, when the input level RFin of the high frequency signal being input is equal to or higher than the predetermined level, is configured by combining the first field effect transistor 1 and the second field effect transistor 2, and thereby the signal processing circuit 100 according to the embodiment of the present invention can be configured using a small number of elements. Thus, it is possible to easily provide the signal processing circuit which has the output signal adjustment circuit and a small circuit size.

The present invention is not limited to the description of the above-described embodiments, and can be implemented by appropriately modifying in a manner that the effect is exhibited. For example, in the signal processing circuit according to the embodiment of the present invention, configuration elements equivalent to the configuration elements illustrated in FIG. 1 may be included.

It should be understood by those skilled in the art that various modifications, combinations, sub-combinations and alterations may occur depending on design requirements and other factors insofar as they are within the scope of the appended claims of the equivalents thereof.

1. A signal processing circuit comprising:
a detection circuit configured to detect detecting a high frequency signal being input; and
an output signal adjustment circuit coupled to an output end of the detection circuit, the output signal adjustment circuit including:
a first field effect transistor having a drain connected to the output end of the detection circuit, a source outputting an output signal and a gate; and
a second field effect transistor having a drain connected to the gate of the first field effect transistor, has a source connected to a ground, and a gate connected to the source of the first field effect transistor,
wherein when an input level of the high frequency signal is equal to or higher than a predetermined level, a magnitude of the output signal is maintained at a predetermined magnitude.

2. The signal processing circuit according to claim 1, further comprising:
a power supply terminal;
a first resistor connected from the gate of the first field effect transistor to the power supply terminal;
a second resistor connected from a connection point between the gate of the first field effect transistor and the first resistor to the drain of the second field effect transistor;
a third resistor connected from the source of the second field effect transistor to the ground; and
a fourth resistor connected from the source of the first field effect transistor to the ground.

3. The signal processing circuit according to claim 1, further comprising:
a smoothing circuit including the fourth resistor and a capacitor connected from an output terminal to the ground in parallel to the fourth resistor, the fourth resistor being shared by the output signal adjustment circuit and the smoothing circuit.
